(19) United States
(12) Patent Application Publication
(10) Pub. No.: US 2007/0023818 A1
(43) Pub. Date: Feb. 1, 2007

(54) Flash memory and method for manufacturing thereof

(76) Inventors: Chia-Hua Ho, Hsinchu (TW); Erh-Kun Lai, Hsinchu (TW)

Correspondence Address: J C PATENTS, INC., 4 VENTURE, SUITE 250, IRVINE, CA, 92618, US

(21) Appl. No.: 11/195,264

(22) Filed: Aug. 1, 2005

(51) Int. Cl. H01L 29/788

(52) U.S. Cl. 257/315; 438/211; 257/E29.129

(57) ABSTRACT

The invention is directed to a flash memory comprising a first source/drain region, a second source/drain region, a first floating gate, a second floating gate, a lightly doped region and a control gate. The first source/drain region and the second source/drain region are located in the substrate and apart from each other. The first floating gate and the second floating gate are isolated from each other and are located on the substrate between the first and the second source/drain regions, wherein the first floating gate is close to the first source/drain region and the second floating gate is close to the second source/drain region. The lightly doped region is located in the substrate between the first and the second floating gates. Also, the control gate is located over the substrate and isolated from the first and the second floating gates.

### BACKGROUND OF THE INVENTION

1. Field of Invention

The present invention relates to a semiconductor device and a method for forming the same. More particularly, the present invention relates to a flash memory and a method for manufacturing thereof.

2. Description of Related Art

Memory, so to speak, is a semiconductor device for storing data or information. When the function of a computer microprocessor becomes more powerful and the programs and computation of the software gets more complicated, the demand for the capacity of a memory increases accordingly. In order to satisfy the trend of the demand mentioned above, the technology and process to manufacture the inexpensive memory with high capacity has become the drive for manufacturing a high integrated device.

Among various memory products, non-volatile memory, having the ability for performing store, read, or erase data repeatedly and without loss of data after disconnection of power, has become a semiconductor device widely accepted by personal computer and electronic equipment. Flash memory is a kind of non-volatile memory and possesses the advantages including high speed reading and writing ability and high memory storage density.

Flash memory is applied to many industries including communication industry, consumer electronics industry, data processing industry and transportation industry. With the highly demanding on smaller and smaller electronic equipments, how to decrease the size of the flash memory with the increase of the memory storage density and to decrease manufacturing cost becomes the main study task in the current manufacturing technology.

### SUMMARY OF THE INVENTION

Accordingly, at least one objective of the present invention is to provide a flash memory structure capable of storing at least two carriers for a unit flash memory.

At least another objective of the present invention is to provide a method for manufacturing a flash memory. By using the method according to the present invention, the profile of the floating gate is uniform and the cost is decreased.

To achieve these and other advantages and in accordance with the purpose of the invention, as embodied and broadly described herein, the invention provides a flash memory for a substrate. The flash memory comprises a first source/drain region, a second source/drain region, a first floating gate, a second floating gate, a lightly doped region and a control gate. The first source/drain region is located in the substrate and the second source/drain region is located apart from the first source/drain region in the substrate. Further, the first floating gate is located on the substrate between the first source/drain region and the second source/drain region, wherein the first floating gate is close to the first source/drain region. The second floating gate is located on the substrate between the first source/drain region and the second source/drain region, wherein the second floating gate is close to the second source/drain region and the first floating gate is isolated from the second floating gate. The lightly doped region is located in the substrate between the first floating gate and the second floating gate. Also, the control gate is located over the substrate and isolated from the first floating gate and the second floating gate.

In the present invention, the source/drain region and the lightly doped region possess the same conductive type. The flash memory of the present invention further comprises several pocket implant doped regions located in the substrate between the first source/drain region and the second source/drain region and adjacent to the first source/drain region and the second source/drain region respectively. Moreover, the first floating gate and the second floating gate are isolated from the substrate by a tunnel dielectric layer. The first floating gate and the second floating gate are isolated from the control gate by a dielectric layer with a dielectric constant larger than 4.

The present invention also provides a method for forming a flash memory on a substrate having a conductive layer and a hard mask layer formed thereon. The method comprises steps of patterning the hard mask layer and the conductive layer to form a plurality of first openings in the conductive layer and then forming a plurality of source/drain regions in the substrate right under the bottom of the first openings respectively. Also, a plurality of dielectric plugs is formed to fill out the first openings respectively. Then, the hard mask layer is removed. Thereafter, a multi-layered spacer is formed on the patterned conductive layer and on the sidewall of the dielectric plugs, wherein a portion of the conductive layer is exposed by the multi-layered spacer. An etching process is performed to form a second opening in the patterned conductive layer so as to divide the patterned conductive layer into a first floating gate and a second floating gate. A self-aligned lightly doped region is formed in the substrate under the bottom of the second opening and then a first dielectric layer is formed to fill out the second opening. A planarization process is performed until the top surfaces of the first floating gate and the second floating gate are exposed. A control gate is formed over the substrate.

In the present invention, the step of forming a multi-layered spacer comprises steps of forming a conformal dielectric layer over the substrate, forming a second dielectric layer on the conformal dielectric layer and then performing an etching process to remove a portion of the second dielectric layer and a portion of the conformal dielectric layer until a portion of the patterned conductive layer is exposed. Under the circumstances mentioned above, the step of performing the planarization process comprises steps of performing a chemical mechanical polishing (CMP) process by using a portion of the conformal dielectric layer on the top surfaces of the first floating gate and the second floating gate as an etching stop layer and then removing the rest of the conformal dielectric layer until the top surfaces of the first floating gate and the second floating gate are exposed. Furthermore, the aforementioned step of removing the rest of the conformal dielectric layer can be accomplished by performing an over-polishing CMP process, a wet etching process or a dry etching process. Also, the polishing selective ratio of the conformal dielectric layer to the second dielectric layer is of about 500. The conformal dielectric layer is made of silicon nitride and the second dielectric layer is made of silicon oxy nitride. More specifically, the second dielectric layer is made from a material as same as that used to form the dielectric plugs and the first dielectric layer. Furthermore, the steps of forming the dielectric plugs and removing the hard mask layer comprise steps of forming a third dielectric layer over the substrate to form the dielectric plugs filling out the openings respectively, performing a wet dipping process to remove a portion of the third dielectric layer so that a portion of the top portion of the patterned hard mask layer is exposed and then performing a lift-off process to remove the patterned hard mask layer together with a portion of the third dielectric layer over the patterned hard mask layer. Under the situation mentioned above, the lift-off process can be accomplished by using dilute hydrogen fluoride, buffer hydrogen fluoride or hot phosphoric acid. Further, the step of forming the self-aligned lightly doped region can be accomplished by implanting dopants with an ion concentration of about 10¹⁸ ions/cm³ and an implanting energy of about 10 keV.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1H are cross-sectional views illustrating a method for manufacturing a flash memory according to one preferred embodiment of the present invention.

FIG. 2. is a cross-sectional view of a flash memory of another preferred embodiment of the present invention.

### DESCRIPTION OF THE PREFERRED EMBODIMENTS

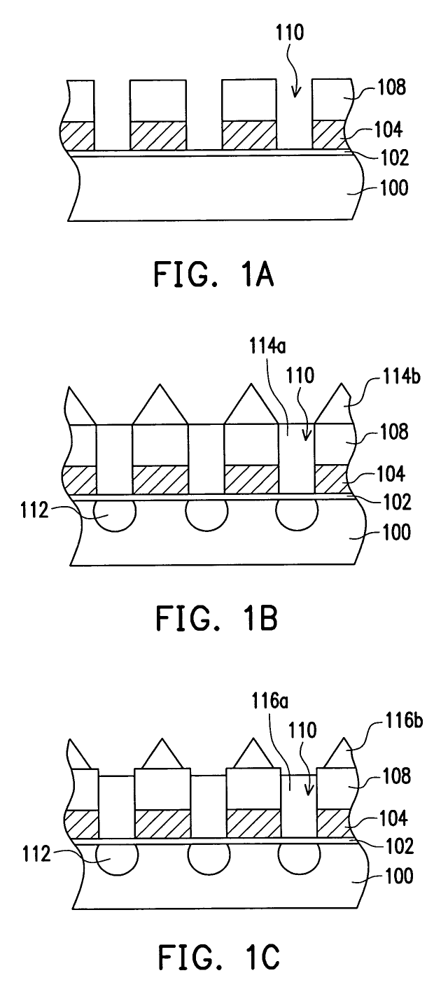

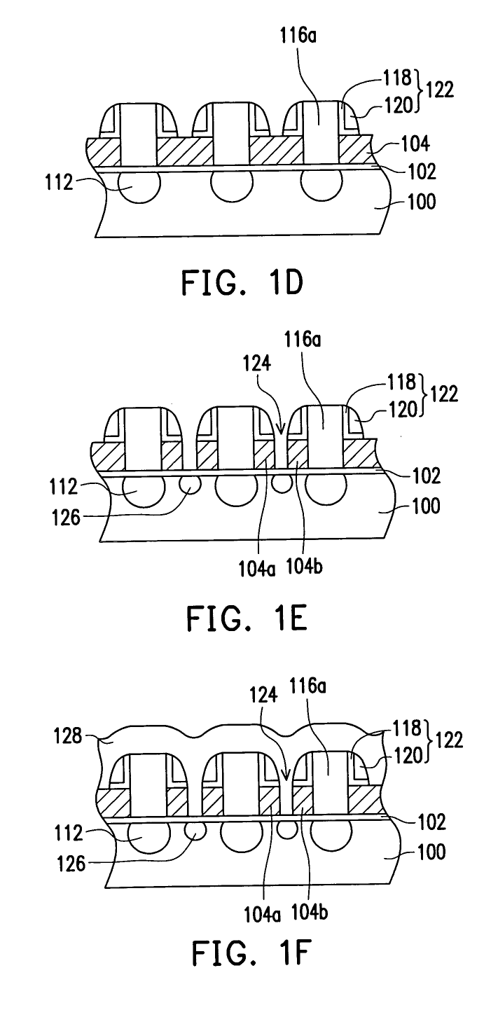

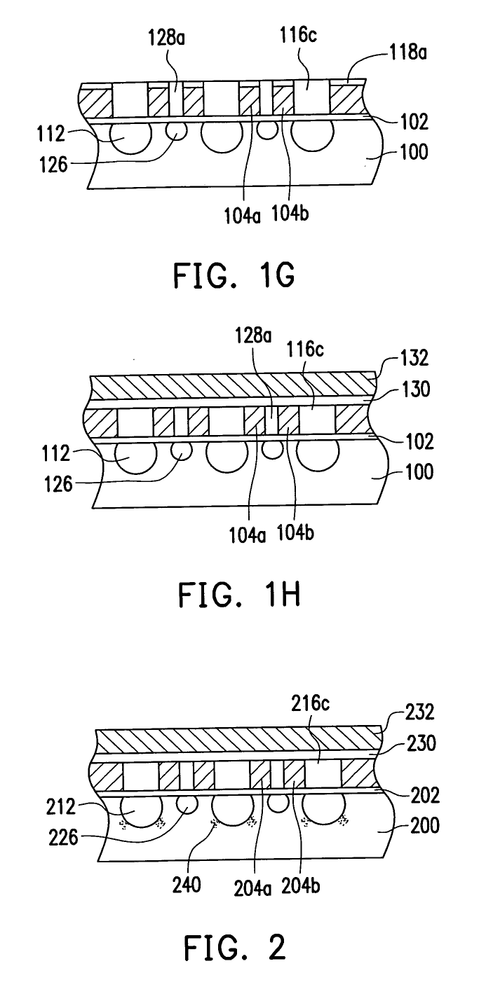

FIGS. 1A through 1H are cross-sectional views illustrating a method for manufacturing a flash memory according to one preferred embodiment of the present invention.

As shown in FIG. 1, a substrate 100 having a tunnel dielectric layer 102, a conductive layer (not shown) and a hard mask layer (not shown) formed thereon is provided. The conductive layer is located on the tunnel dielectric layer 102 and the hard mask layer is located on the conductive layer. The tunnel dielectric layer 102 can be, for example but not limited to, made from silicon oxide, aluminum oxide, hafnium oxide, silicon nitride or silicon oxy nitride. The tunnel dielectric layer 102 can be, for example but not limited to, formed by performing a low-pressure-chemical-vapor-deposition (LPCVD) process. Furthermore, the thickness of the tunnel dielectric layer 102 is of about 5-15 nm. Moreover, the conductive layer can be, for example but not limited to, made of polysilicon, doped polysilicon, metal silicide or metal. The thickness of the conductive layer is of about 40-100 nm. Also, the hard mask layer can be, for example but not limited to, made of silicon oxide or silicon nitride and the thickness of the hard mask layer is of about 50-200 nm.

Thereafter, the hard mask layer and the conductive layer are pattern to form the conductive layer 104 and the hard mask layer 108 with several first openings 110 formed therein. In this embodiment, the first openings 110 only penetrate through the hard mask layer 108 and the conductive layer 104 and expose a portion of the tunnel dielectric layer 102. However, the configuration of the first openings 110 illustrated in this embodiment does not limit the scope of the present invention. That is, with the variation of the manufacture demands, the first openings 110 can be also penetrating through the tunnel dielectric layer 102 to expose a portion of the substrate 100.

As shown in FIG. 1B, several source/drain regions 112 are formed in the substrate 100 right under the bottom of the first openings 110 respectively. The method for forming the source/drain regions 112 comprises a step of performing an ion implantation process for implanting ions with the ion concentration of about 10¹⁹-10²⁰ ions/cm³ into the substrate 100. Moreover, the ions implanted into the substrate 100 can be, for example but not limited to, arsenic ions, nitrogen ions or phosphorous ions.

Furthermore, several dielectric plugs 114a are formed to fill out the first openings 110 respectively. The method for forming the dielectric plugs 114a comprises the step of covering the substrate 100 with a dielectric material to form the dielectric layer 114b on the hard mask layer 108 and the dielectric plugs 114a in the openings 110 respectively. The dielectric material can be, for example but not limited to, silicon nitride, silicon oxide or the dielectric material with different wet etching behavior from the hard mask layer 108. Also, the thickness of the dielectric layer composed of the dielectric layer 114b and the dielectric plugs 114a is of about 80-300 nm.

As shown in FIG. 1C, a wet dipping process is performed to remove a portion of the dielectric layer 114b and the plugs 114a and transform the dielectric layer 114b and the plugs 114a into the dielectric layer 116b and the plugs 116a. Hence, a portion of the top portion of the hard mask layer 108 is exposed by the dielectric layer 116b and the plugs 116a. While the dielectric layer composed of the dielectric layer 114b and the dielectric plugs 114a is made of silicon oxide, the wet dipping process can be accomplished by using dilute hydrogen fluoride or buffer hydrogen fluoride. Alternatively, while the dielectric layer composed of the dielectric layer 114b and the dielectric plugs 114a is made of silicon nitride, the wet dipping process can be accomplished by using hot phosphoric acid.

Thereafter, as shown in FIG. 1D, a lift-off process is performed to remove the hard mask layer 108 together with the dielectric layer 116b over the hard mask layer 108. While the hard mask layer 108 is made of silicon oxide, the wet dipping process can be accomplished by using dilute hydrogen fluoride or buffer hydrogen fluoride. Alternatively, while the hard mask layer is made of silicon nitride, the wet dipping process can be accomplished by using hot phosphoric acid.

Furthermore, a multi-layered spacer 122 is formed on the conductive layer 104 and on the sidewall of the dielectric plugs 116a, wherein a portion of the conductive layer 104 is exposed by the multi-layered spacer 122. The method for forming the multi-layered spacer 122 comprises the steps of forming a conformal dielectric layer (not shown) over the substrate 100 and then forming a dielectric layer (not shown) on the conformal dielectric layer and performing an etching process to remove a portion of the dielectric layer and a portion of the conformal dielectric layer until a portion of the conductive layer 104 is exposed. Therefore, the conformal dielectric layer and the dielectric layer is transformed into an L-shape spacer 118 and a spacer 120 respectively and the L-shape spacer 118 and the spacer 120 together form the multi-layered spacer 122. Moreover, the polishing selective ratio of the conformal dielectric layer (i.e. L-shape spacer 118) to the dielectric layer (i.e. the spacer 120) is of about 500. Also, the conformal dielectric layer (i.e. L-shape spacer 118) can be, for example but not limited to, made from silicon nitride by using the chemical vapor deposition (CVD) process or the plasma-enhanced CVD process. The dielectric layer (i.e. the spacer 120) can be, for example but not limited to, made of silicon oxy nitride. More specifically, the dielectric layer (i.e. the spacer 120) is made from a material as same as that used to form the dielectric plugs 116a.

As shown in FIG. 1E, by using the multi-layered spacer 122 and the dielectric plugs 116a as masks, an etching process is performed to form a second opening 124 in the conductive layer 104 so as to divide the conductive layer 104 into a first floating gate 104a and a second floating gate 104b. In this embodiment, the second opening only penetrates through the conductive layer 104 (as shown in FIG. 1D) and exposes a portion of the tunnel dielectric layer 102. However, the configuration of the second opening 124 illustrated in this embodiment does not limit the scope of the present invention. That is, with the variation of the manufacture demands, the second opening 124 can be also penetrating through the tunnel dielectric layer 102 to expose a portion of the substrate 100.

In addition, a self-aligned lightly doped region 126 is formed in the substrate 100 under the bottom of the second opening 124. The step of forming the self-aligned lightly doped region 126 can be accomplished by implanting dopants with an ion concentration of about 10¹⁸ ions/cm³ and an implanting energy of about 10 keV. Furthermore, the dopants can be, for example but not limited to, arsenic ions, nitrogen ions or phosphorous ions.

As shown in FIG. 1F, a dielectric layer 128 is formed to fill out the second opening 124. The dielectric layer 128 can be made of a dielectric material as same as that used to form the dielectric plug 116a and the spacer 120 and the dielectric layer 128 can be formed by using the LPCVD process.

As shown in FIG. 1G together with FIG. 1H, a planarization process is performed until the top surfaces of the first floating gate 104a and the second floating gate 104b are exposed. The method for performing the planarization process comprises steps of performing a chemical mechanical polishing (CMP) process to remove a portion of the dielectric layer 128 and the multi-layered spacer 122 by using a portion of the L-shape spacer 118 (as shown in FIG. 1F) on the top surfaces of the first floating gate 104a and the second floating gate 104b as an etching stop layer and then removing the rest of the L-shape spacer 118 until the top surfaces of the first floating gate 104a and the second floating gate 104b are fully exposed. Moreover, the step of removing the rest of L-shape spacer 118 can be, for example but not limited to, accomplished by performing an over-polishing CMP process, a wet etching process or a dry etching process. In the planarization process, at the beginning of the CMP process, since the dielectric layer 128, the spacer 120 and the dielectric plugs 116a are formed from the same material and the polished amount of the L-shape spacer 118 is very small, the polishing rate remains stable. However, while most of the spacer 118 is removed and the polished amount of the L-shape spacer 118 is dramatically increased, because of the polishing selective ratio of the L-shape spacer 118 to the dielectric layer (i.e. the spacer 120 and the dielectric plug 116a), the CMP process stops. After the planarization process, the remaining dielectric plugs is labeled 116c and the remaining dielectric layer in the second opening 124 is labeled 128a.

As shown in FIG. 1H, a dielectric layer 130 is formed over the substrate 100. The dielectric layer 130 can be a dielectric layer with a dielectric constant larger than 4. Preferably, the dielectric layer 130 can be, for example but not limited to, a silicon oxide/silicon nitride/silicon oxide layer or a silicon oxide/high k material/silicon oxide layer. The high k material can be a material possesses a dielectric constant larger than 4. Also, the high k material can be, for example but not limited to, aluminum oxide, hafnium oxide, silicon nitride or silicon oxy nitride. Thereafter, a control gate 132 is formed over the substrate 100. The control gate 132 can be, for example but not limited to, made of polysilicon, doped polysilicon, metal silicide or metal and the thickness of the control gate 132 is of about 40-200 nm.

Still referring to FIG. 1H, the present invention further provides a flash memory structure. The flash memory structure according to the present invention comprises several source/drain regions 112 located in the substrate, the first floating gate 104a and the second floating gate 104b located on the substrate 100 between the source/drain regions 112, wherein the first floating gate 104a and the second floating gate 104b are isolated from each other and are close to the source/drain regions 112 respectively. The flash memory further comprises the lightly doped region 126 located in the substrate 100 between the first floating gate 104a and the second floating gate 104b. Also, the control gate 132 is located over the substrate 100 and isolated from the first floating gate 104a and the second floating gate 104b by using the dielectric layer 130 with a dielectric constant larger than 4. In addition, the source/drain region 112 and the lightly doped region 126 possess the same conductive type. Moreover, the first floating gate 104a and the second floating gate 104b are isolated from the substrate by the tunnel dielectric layer 102.

FIG. 2. is a cross-sectional view of a flash memory of another preferred embodiment of the present invention. As shown in FIG. 2, the flash memory according to another preferred embodiment of the present invention further comprises several pocket implant doped regions 240 located in the substrate 200 between the source/drain regions 212 and adjacent to the source/drain regions 212 respectively. The pocket implant doped regions 240 can be formed by implanting ions with the conductive type different from that of the source/drain regions 212 into the substrate 200. The ion concentration of the ions implanted into the substrate 200 to form the pocket implant doped regions 240 is of about 10¹⁶-10¹⁸ ions/cm³ and the ions can be boron ions or boron fluoride.

In the present invention, since the conductive layer 104 is divided into the first floating gate 104a and the second floating gate 104b by the dielectric layer 128a, each of the first floating gate 104a and the second floating gate can store at least one carrier. Hence, for the unit memory cell, the memory density is increased. Moreover, by using the dielectric plugs 116a and the multi-layered spacer 122 as masks, the lightly doped region 126 is self-aligned formed in the substrate 100 without using additional photolithography process. Hence, the cost is decreased. Furthermore, by using a portion of the L-shape spacer 118 located on the surfaces of the first floating gate 104a and the second floating gate 104b as the etching stop layer, the CMP process performed for removing the dielectric layer 128, the spacer 120 and the dielectric plug 116a can be well controlled. Therefore, the profile of the first floating gate 104a and the second floating gate 104b after the planarization process is more uniform.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A flash memory for a substrate comprising:
a first source/drain region located in the substrate;
a second source/drain region located apart from the first source/drain region in the substrate;
a first floating gate located on the substrate between the first source/drain region and the second source/drain region, wherein the first floating gate is close to the first source/drain region;
a second floating gate located on the substrate between the first source/drain region and the second source/drain region, wherein the second floating gate is close to the second source/drain region and the first floating gate is isolated from the second floating gate;
a lightly doped region located in the substrate between the first floating gate and the second floating gate; and
a control gate located over the substrate and isolated from the first floating gate and the second floating gate,
wherein the first and the second floating gates are located close to each other and separated by a dielectric layer.

2. The flash memory of claim 1, wherein the source/drain region and the lightly doped region possess the same conductive type.

3. The flash memory of claim 1 further comprising a plurality of pocket implant doped regions located in the substrate between the first source/drain region and the second source/drain region and adjacent to the first source/drain region and the second source/drain region respectively.

4. The flash memory of claim 1, wherein the first floating gate and the second floating gate are isolated from the substrate by a tunnel dielectric layer.

5. The flash memory of claim 1, wherein the first floating gate and the second floating gate are isolated from the control gate by a dielectric layer with a dielectric constant larger than 4.

6-16. (canceled)
